(19) United States
(12) Patent Application Publication
(10) Pub. No.: US 2016/0091754 A1
(43) Pub. Date: Mar. 31, 2016

(54) DISPLAY DEVICE

(71) Applicant: SHARP KABUSHIKI KAISHA, Osaka (JP)

(72) Inventor: Hisashi WATANABE, Osaka (JP)

(73) Assignee: Sharp Kabushiki Kaisha, Osaka (JP)

(21) Appl. No.: 14/785,072

(22) PCT Filed: Feb. 27, 2014
(86) PCT No.: PCT/JP2014/054890

§ 371 Date: Oct. 16, 2015

(30) Foreign Application Priority Data
Apr. 26, 2013 (JP) 2013-094306

(51) Int. Cl. G02F 1/1335; H01L 27/32; H01L 51/52; G02F 1/1343

(52) U.S. Cl. CPC G02F 1/133514; G02F 1/133528; G02F 1/134336; H01L 27/3218; H01L 51/5262; H01L 51/5253; G02F 2001/133562

(57) ABSTRACT

A display device includes a color display panel and an optical member arranged on the viewer's side of the color display panel. The color display panel includes a display region in which a plurality of color display pixels are arranged into rows and columns to form a matrix pattern. The display region includes a first display region and a second display region in which different arrangement patterns are used for primary color pixels. The first display region employs a first pattern in which primary color pixels of the same color are arranged in the column direction. The second display region employs a second pattern in which primary color pixels of different colors are arranged in the column direction in a repeating pattern. The second display region includes at least one column of color display pixels positioned on one end of the display region in the row direction.

### TECHNICAL FIELD

The present invention relates to a display device, and more particularly to a color display device.

### BACKGROUND ART

In display devices in which primary color pixels are arranged in a regular pattern (such as in liquid crystal display devices and organic electroluminescent display devices), a rainbow-like coloring effect can sometimes be seen near the edge of the display device. In the following description, this effect will be referred to simply as the “rainbow effect” for simplicity. This type of rainbow effect occurs when, near the edges of the display device, the edges of an optical member (such as a polarizing plate or a transparent cover) arranged on the viewer's side of the display panel are slanted relative to the regular arrangement of the primary color pixels. The reason why this rainbow effect occurs will be described below with reference to FIG. 10.

FIGS. 10(a) and 10(b) schematically illustrate regions near the edges of a color liquid crystal display device 900. FIG. 10(a) schematically illustrates an edge region parallel to a vertical direction of the display surface (a direction running from 6 o'clock to 12 o'clock on the display surface in terms of clock positions). FIG. 10(b) schematically illustrates an edge region parallel to a horizontal direction of the display surface (a direction running from 3 o'clock to 9 o'clock on the display surface in terms of clock positions). The liquid crystal display device 900 includes a color liquid crystal display panel 900a and an optical member 900b (such as a polarizing plate) arranged on the viewer's side of the liquid crystal display panel 900a. Note that in the present specification, the display panel is defined to include a transparent viewer-side substrate but does not include the optical members such as polarizing plates or the like that are arranged on the viewer's side.

The liquid crystal display panel 900a includes three types of primary color pixels: red (R) pixels, green (G) pixels, and blue (B) pixels. Each group of three of these primary color pixels forms a single color display pixel. The primary color pixels are arranged in rows and columns to form a matrix pattern. Typically, the column direction is parallel to the vertical direction, and the row direction is parallel to the horizontal direction. Moreover, in TFT liquid crystal display panels, source bus lines run parallel to the column direction, and gate bus lines run parallel to the row direction.

A polarizing plate 900b, for example, is arranged on the viewer's side of the liquid crystal display panel 900a. If the edges of the polarizing plate 900b are curved, as illustrated in FIG. 10, or if the edges of the polarizing plate 900b are slanted relative to the column direction of the primary color pixels due to imprecise alignment relative to the liquid crystal display panel 900a, this causes a variation in the strength of the light emitted from the primary color pixels, thereby creating the rainbow effect near the edges of the polarizing plate 900b, as shown in FIG. 10(a).

Meanwhile, as illustrated in FIG. 10(b), in edge regions parallel to the horizontal direction, the rainbow effect does not occur even if the edges of the polarizing plate 900b and the edges of the liquid crystal display panel 900a do not align (that is, even if the edges of the polarizing plate 900b are curved or if the edges of the polarizing plate 900b are slanted relative to the column direction of the primary color pixels). Edge regions parallel to the horizontal direction run in a direction that intersects with different colors of primary color pixels. Therefore, just like in non-edge regions, the primary colors blend effectively and the rainbow effect does not occur.

Patent Document 1 discloses a liquid crystal display device in which the primary color pixels in each color display pixel are arranged in the column direction rather than in the conventional row direction, and therefore, different colors of primary color pixels are arranged along the edges parallel to the vertical direction (such as the edge illustrated in FIG. 10(a)).

### RELATED ART DOCUMENT

### Patent Document

Patent Document 1: Japanese Patent No. 3946547

### SUMMARY OF THE INVENTION

### Problems to be Solved by the Invention

However, in the liquid crystal display device disclosed in Patent Document 1, although the rainbow effect does not occur along edges parallel to the vertical direction, the rainbow effect still occurs along edges parallel to the horizontal direction (that is, opposite to the case illustrated in FIG. 10(b)). Therefore, the rainbow effect cannot be prevented along both the vertical and horizontal edges.

Moreover, in the liquid crystal display device disclosed in Patent Document 1, while the primary color pixels in each color display pixel are changed to being arranged in the column direction, the directions in which the source bus lines and the gate bus lines run is not modified. Therefore, the wires (drain leads) for connecting the drain electrodes of the TFTs to the pixel electrodes of the primary color pixels must be arranged within the color display pixels. This complicates the wiring of the liquid crystal display device disclosed in Patent Document 1 and can also decrease the aperture ratio of the pixels.

Here, a liquid crystal display device utilizing a stripe pattern configuration in which primary color pixels of the same color are aligned in the column direction was used as a typical example. However, rows and columns are conceptually interchangeable, and therefore all color display devices that include at least one column (or row) in which primary color pixels of the same color are aligned are subject to the abovementioned problems.

The present invention was made in order to solve at least one of the abovementioned problems and aims to reduce the occurrence of the rainbow effect near the edges of a color display device.

### Means for Solving the Problems

According to one embodiment of the present invention, a display device includes: a color display panel including a transparent substrate arranged on a viewer's side; and an optical member arranged on the viewer's side of the color display panel, wherein the color display panel includes a display region in which a plurality of color display pixels are arranged into rows and columns to form a matrix pattern, wherein each of the plurality of color display pixels includes a plurality of primary color pixels of different colors arranged in a row direction, wherein the display region includes a first display region and a second display region having mutually different arrangement patterns of the colors of the primary color pixels, such that the first display region has a first pattern in which the primary color pixels of a same color are arranged in a column direction, and such that the second display region has a second pattern in which the primary color pixels of different colors are repeated in the column direction at a prescribed interval, and wherein the second display region includes at least one column of the color display pixels positioned on one end of the display region in the row direction.

In one embodiment, in the second pattern, the primary color pixels of different colors are arranged every k primary color pixel interval in the column direction, where k is a positive integer less than or equal to 3.

In one embodiment, tan⁻¹(Px/(k·Py)) is less than or equal to 25°, where Px is an arrangement pitch of the primary color pixels in the row direction and Py is an arrangement pitch of the primary color pixels in the column direction.

In one embodiment, when a color display pixel in the mth row and Nth column in the matrix is written as m·N(n₁, n₂, . . . , nₚ₋₁, nₚ), where (n₁, n₂, . . . , nₚ₋₁, nₚ) represents primary color pixels of first, second, . . . , (p−1)th, and pth colors arranged in order from left to right in the row direction, then a color display pixel in the (m+k)th row and Nth column in the matrix is written as (m+k)·N(nₚ, n₁, n₂, . . . , nₚ₋₁), and a color display pixel in the (m+2k)th row and Nth column in the matrix is written as (m+2k)·N(nₚ₋₁, nₚ, n₁, . . . , nₚ₋₂) (where, m, N, and n are positive integers, k is a positive integer less than or equal to 3, and p is an integer greater than or equal to 3 and less than or equal to 6).

In one embodiment, when a color display pixel in the mth row and Nth column in the matrix is written as m·N(n₁, n₂, n₃, n₄), where (n₁, n₂, n₃, n₄) represents primary color pixels of first, second, third, and fourth colors arranged in order from left to right in the row direction, then a color display pixel in the (m+k)th row and Nth column in the matrix is written as (m+k)·N(n₂, n₁, n₄, n₃). (Here, m, N, and n are positive integers, and k is a positive integer less than or equal to 3).

In one embodiment, the first, second, and third colors are red, green, and blue, respectively, and the fourth color is white or yellow.

In one embodiment, the optical member includes an edge line or a boundary line parallel to an edge of the color display panel in the row direction, and when L is a length from the edge of the color display panel in the row direction to the edge line or the boundary line when the transparent substrate is viewed from a direction normal thereto, Ts is a thickness of the transparent substrate, and To is a thickness of the optical member along the edge line or the boundary line, then X satisfies X≧L+0.2 mm, where X is a length from the edge of the color display panel in the row direction to a boundary between the first display region and the second display region on one end of the display region. It is more preferable that the length X satisfy X≧L+0.35×(Ts+To)+0.2 mm.

In one embodiment, the length X from the edge of the color display panel in the row direction to the boundary between the first display region and the second display region on one end of the display region satisfies X≦L+0.88×(Ts+To)+0.2 mm.

In one embodiment, the optical member includes a flat portion where a surface of the optical member on the viewer's side is flat, and a lens portion adjacent to the flat portion in the row direction, and the boundary line is a boundary line between the flat portion and the lens portion.

In one embodiment, the second display region further includes one column of the color display pixels positioned on another end of the display region in the row direction.

In one embodiment, the primary color pixels respectively include color filters.

In one embodiment, the color display panel is a liquid crystal display panel, and the optical member includes a polarizing plate and a transparent cover arranged in that order from the transparent substrate side of the color display panel.

In one embodiment of the present invention, a display device includes: a color display panel including a transparent substrate arranged on a viewer's side; and an optical member arranged on the viewer's side of the color display panel, wherein the color display panel includes a display region in which a plurality of color display pixels are arranged into rows and columns to form a matrix pattern, wherein each of the plurality of color display pixels includes a plurality of primary color pixels of different colors arranged in a row direction, wherein the display region includes a first display region and a second display region having mutually different arrangement patterns of the colors of the primary color pixels, such that the first display region has a first pattern having a PenTile structure that includes primary color pixel columns in which the primary color pixels having a first color are arranged in the column direction, and such that the second display region has a second pattern in which the columns of the primary color pixels that include the primary color pixels of the first color are arranged such that the primary color pixels of the first color alternate with the primary color pixels of a second color that is different from the first color, and wherein the second display region includes at least one column of the color display pixels positioned on one end of the display region in the row direction.

In one embodiment, the first color is green or blue, and the second color is red.

In one embodiment, the color display panel is an organic electroluminescent display panel, and the optical member includes a circularly polarizing plate and a transparent cover arranged in that order starting from a transparent substrate side of the color display panel.

### Effects of the Invention

The embodiments of the present invention make it possible to reduce the occurrence of the rainbow effect near the edges of a color display device.

### BRIEF DESCRIPTION OF THE DRAWINGS

FIG. 1A schematically illustrates an arrangement of primary color pixels in a liquid crystal display panel 100a of a liquid crystal display device 100 according to an embodiment of the present invention.

FIG. 1B schematically illustrates a corner region of the liquid crystal display device 100.

FIG. 2 is a cross-sectional view schematically illustrating a cross section taken along a line parallel to a row direction in an edge region of the liquid crystal display device 100.

FIG. 3 is a cross-sectional view schematically illustrating a cross section taken along a line parallel to a row direction in an edge region of a liquid crystal display device 100A.

FIG. 4 is a cross-sectional view schematically illustrating a cross section taken along a line parallel to a row direction in an edge region of a liquid crystal display device 100B.

FIGS. 5(a), 5(b), and 5(c) illustrate examples of pixel arrays for a display panel in which each color display pixel Pc includes four primary color pixels P.

FIGS. 6(a) and 6(b) illustrate examples of pixel arrays for a display panel in which each color display pixel Pc includes five primary color pixels P.

FIGS. 7(a) and 7(b) illustrate examples of pixel arrays for a display panel in which each color display pixel Pc includes six primary color pixels P.

FIG. 8A(a) illustrates a pattern in which a different color of primary color pixel is used every one primary color pixel. FIG. 8A(b) schematically illustrates a case in which this pattern is used to display a straight red (R) line.

FIG. 8B(a) illustrates a pattern in which a different color of primary color pixel is used every two primary color pixels. FIG. 8B(b) schematically illustrates a case in which this pattern is used to display a straight red (R) line.

FIG. 8C(a) illustrates a pattern in which a different color of primary color pixel is used every three primary color pixels. FIG. 8C(b) schematically illustrates a case in which this pattern is used to display a straight red (R) line.

FIG. 9(a) illustrates a pattern having a PenTile structure. FIG. 9(b) illustrates a primary color pixel array that can reduce the occurrence of the rainbow effect.

FIGS. 10(a) and 10(b) schematically illustrate regions near the edges of a color liquid crystal display device 900. FIG. 10(a) schematically illustrates an edge region parallel to a vertical direction of the display surface. FIG. 10(b) schematically illustrates an edge region parallel to a horizontal direction of the display surface.

### DETAILED DESCRIPTION OF EMBODIMENTS

Next, a display device according to an embodiment of the present invention will be described with reference to figures. The following description focuses primarily on a liquid crystal display device. However, the display device according to the embodiment of the present invention is not limited to liquid crystal display devices and may also be an organic electroluminescent display device, for example.

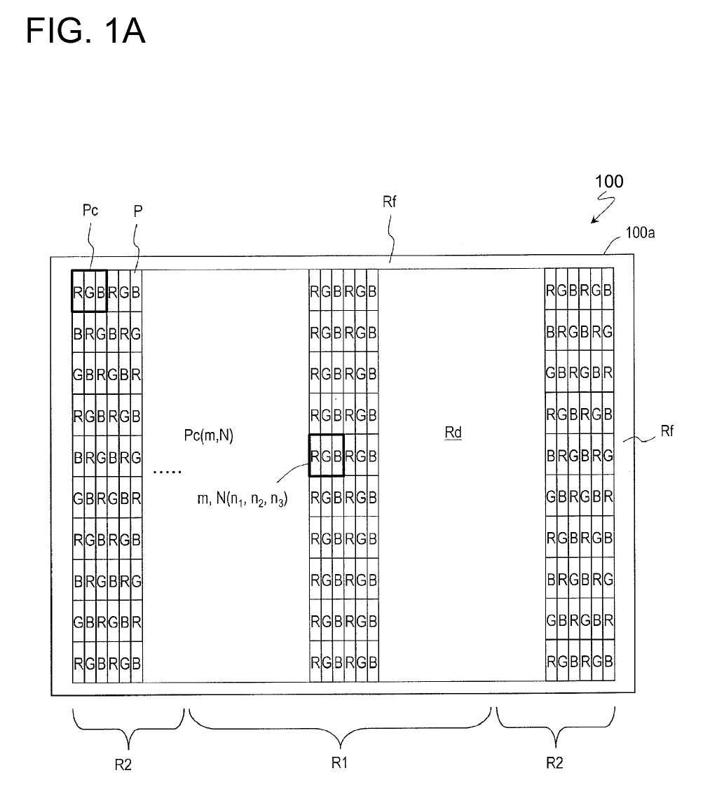

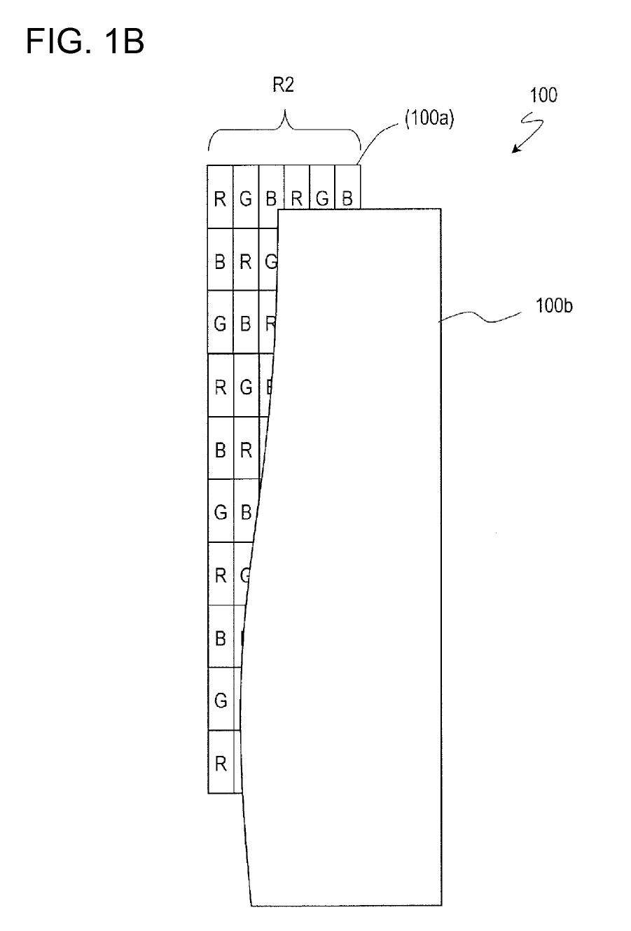

FIG. 1A schematically illustrates an arrangement of primary color pixels in a liquid crystal display panel 100a of a liquid crystal display device 100 according to an embodiment of the present invention.

The liquid crystal display panel 100a includes three types of primary color pixels P: red (R) pixels, green (G) pixels, and blue (B) pixels. Each group of three of these primary color pixels P forms a single color display pixel Pc. In the following description, the primary color pixels P will be referred simply as “pixels P.”

In the liquid crystal display panel 100a, the color display pixels Pc are arranged in a matrix pattern and define a display region Rd. In other words, the display region Rd is the region in which the color display pixels Pc are arranged. The region surrounding the display region Rd is a frame region Rf. The frame region Rf provides a region for forming a sealing member that fixes two glass substrates together and seals a liquid crystal layer between the two substrates, a region for forming driver circuits that send signals used to display images in the display region Rd, and/or a region for mounting external substrates or the like, for example.

Here, Pc(m, N) denotes a color display pixel Pc in the mth row and Nth column in the matrix. P(m, n) denotes a pixel P in the mth row of the matrix and the nth column of the respective color display pixel Pc. The configuration of the color display pixel Pc matrix is described using the following notation. A color display pixel Pc(m, N) in the mth row and Nth column in the matrix can also be written as m·N(n₁, n₂, . . . , nₚ₋₁, nₚ), where (n₁, n₂, . . . , nₚ₋₁, nₚ) represents pixels P of first, second, . . . , (p−1)th, and pth colors arranged in order from left to right in the row direction. In the liquid crystal display panel 100a illustrated in FIG. 1A, for example, a color display pixel Pc(m, N) in the mth row and Nth column in the matrix can also be written as m·N(n₁, n₂, n₃). Each color display pixel Pc(m, N) includes a pixel P(m, n₁) of a first color, a pixel P(m, n₂) of a second color, and a pixel P(m, n₃) of a third color arranged in order from left to right (here, p=3).

The display region Rd of the liquid crystal display panel 100a includes a first display region R1 and a second display region R2 that each uses a different pattern for the colors of pixels P. The first display region R1 uses a first pattern in which the same colors of pixels P are arranged in the column direction. The second display region R2 uses a second pattern in which different colors of primary color pixels are arranged in the column direction in a prescribed repeating pattern. The second display region R2 includes at least one column of color display pixels Pc positioned on one end of the display region Rd in the row direction (the left end in FIG. 1A, for example) and one column of color display pixels Pc positioned on the other end of the display region Rd in the row direction (the right end in FIG. 1A, for example). Moreover, when occurrence of the rainbow effect only needs to be reduced on one end of the display region Rd in the row direction, the second display region R2 may be formed only on that one end, and the first display region R1 may be formed in the rest of the display region Rd.

The first pattern of the first display region R1 includes at least one column of the same color of pixels P arranged in the column direction and is susceptible to the rainbow effect. The first pattern of the first display region R1 of the liquid crystal display panel 100a is a well-known RGB stripe pattern in which pixels P of the same color (R, G, or B) are arranged in the column direction.

Meanwhile, in the second pattern of the second display region R2, different colors of primary color pixels are arranged in the column direction in a prescribed repeating pattern. In the second pattern of the second display region R2 of the liquid crystal display panel 100a, different colors of pixels P are arranged in the column direction in a repeating pattern of three pixel P units (where each R, G, or B pixel is a single unit). Moreover, a different color of pixel P is used every one pixel P in the column direction (in other words, any two pixels adjacent to each other in the column direction have different colors).

In the column of pixels P on the left end of the second display region R2 on the left side of FIG. 1A (the first column), for example, the pixels P are arranged in the following repeating pattern starting from the uppermost row (the first row): R, G, B, R, G, B. In the second column of pixels P from the left in the second display region R2 (the second column), the pixels P are arranged in the following repeating pattern starting from the first row: G, B, R, G, B, R. In the third column, the pixels P are arranged in the following repeating pattern starting from the first row: B, R, G, B, R, G. These relationships hold for the columns of the color display pixels Pc in the second display region R2. Note, however, that the number of columns of pixels P in the second display region is not limited to the number of primary colors used (here, three), nor is the number columns of pixels P in the second display region limited to a multiple of the number of primary colors.

In other words, in the second pattern, when a color display pixel Pc(m, N) in the mth row and Nth column in the matrix is written as m·N(n₁, n₂, . . . , nₚ₋₁, nₚ), where (n₁, n₂, . . . , nₚ₋₁, nₚ) represents primary color pixels of first, second, . . . , (p−1)th, and pth colors arranged in order from left to right in the row direction, then a color display pixel Pc(m+k, N) in the (m+k)th row and Nth column in the matrix can be written as (m+k)·N(nₚ, n₁, n₂, . . . , nₚ₋₁), and a color display pixel Pc(m+2k, N) in the (m+2k)th row and Nth column in the matrix can be written as (m+2k)·N(nₚ₋₁, nₚ, n₁, . . . , nₚ₋₂). (Here, m, N, and n are positive integers, k is a positive integer less than or equal to 3, and p is an integer greater than or equal to 3 and less than or equal to 6). Table 1 shows some specific examples of pixel array configurations.

TABLE 1

| Color Display | Pixel Array Configuration | | | | |
|---|---|---|---|---|---|
| Pixel | General Notation | p = 3 | p = 4 | p = 5 | p = 6 |
| Pc(m, N) | (n1, n2, . . . , np − 1, np) | (n1, n2, n3) | (n1, n2, n3, n4) | (n1, n2, n3, n4, n5) | (n1, n2, n3, n4, n5, n6) |
| Pc(m + 1, N) | (n1, n2, . . . , np − 1, np) | (n1, n2, n3) | (n1, n2, n3, n4) | (n1, n2, n3, n4, n5) | (n1, n2, n3, n4, n5, n6) |
| Pc(m + 2, N) | (n1, n2, . . . , np − 1, np) | (n1, n2, n3) | (n1, n2, n3, n4) | (n1, n2, n3, n4, n5) | (n1, n2, n3, n4, n5, n6) |
| . . . | . . . | . . . | . . . | . . . | . . . |
| Pc(m + k, N) | (np, n1, . . . , np − 2, np − 1) | (n3, n1, n2) | (n4, n1, n2, n3) | (n5, n1, n2, n3, n4) | (n6, n1, n2, n3, n4, n5) |
| Pc(m + k + 1, N) | (np, n1, . . . , np − 2, np − 1) | (n3, n1, n2) | (n4, n1, n2, n3) | (n5, n1, n2, n3, n4) | (n6, n1, n2, n3, n4, n5) |
| Pc(m + k + 2, N) | (np, n1, . . . , np − 2, np − 1) | (n3, n1, n2) | (n4, n1, n2, n3) | (n5, n1, n2, n3, n4) | (n6, n1, n2, n3, n4, n5) |
| . . . | . . . | . . . | . . . | . . . | . . . |
| Pc(m + 2k, N) | (np − 1, np, . . . , np − 3, np − 2) | (n2, n3, n1) | (n3, n4, n1, n2) | (n4, n5, n1, n2, n3) | (n5, n6, n1, n2, n3, n4) |
| Pc(m + 2k + 1, N) | (np − 1, np, . . . , np − 3, np − 2) | (n2, n3, n1) | (n3, n4, n1, n2) | (n4, n5, n1, n2, n3) | (n5, n6, n1, n2, n3, n4) |
| Pc(m + 2k + 2, N) | (np − 1, np, . . . , np − 3, np − 2) | (n2, n3, n1) | (n3, n4, n1, n2) | (n4, n5, n1, n2, n3) | (n5, n6, n1, n2, n3, n4) |
| . . . | . . . | . . . | . . . | . . . | . . . |
| Pc(m + 3k, N) | (np − 2, np − 1, np, . . . , np − 3) | (n1, n2, n3) | (n2, n3, n4, n1) | (n3, n4, n5, n1, n2) | (n4, n5, n6, n1, n2, n3) |
| Pc(m + 3k + 1, N) | (np − 2, np − 1, np, . . . , np − 3) | (n1, n2, n3) | (n2, n3, n4, n1) | (n3, n4, n5, n1, n2) | (n4, n5, n6, n1, n2, n3) |
| Pc(m + 3k + 2, N) | (np − 2, np − 1, np, . . . , np − 3) | (n1, n2, n3) | (n2, n3, n4, n1) | (n3, n4, n5, n1, n2) | (n4, n5, n6, n1, n2, n3) |

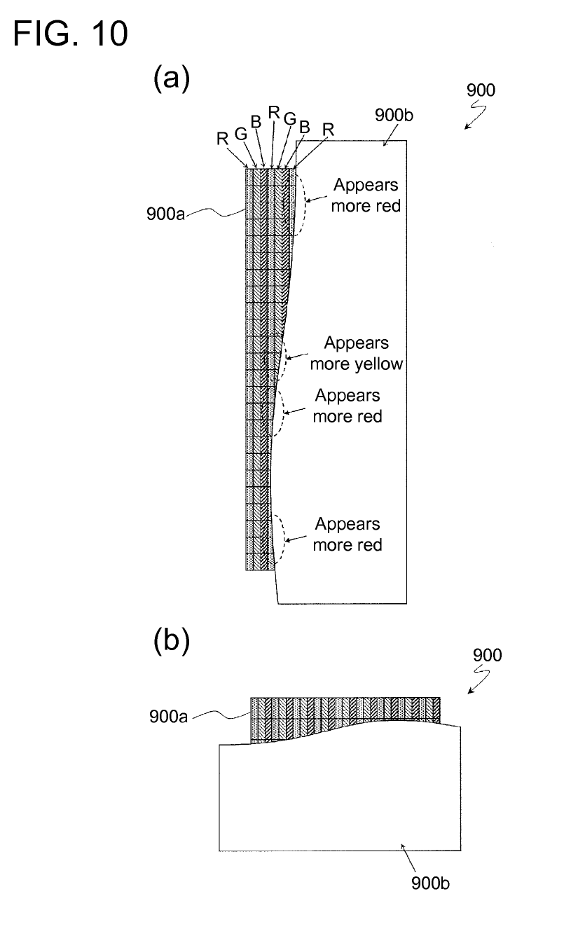

As illustrated in FIG. 1B for example, in the liquid crystal display device 100 having this type of arrangement for the pixels P, occurrence of the rainbow effect is reduced in the corner region on the left end of the display region Rd of the liquid crystal display panel 100a (that is, in the second display region R2) even when the edge of the polarizing plate 100b does not align with the edge of the liquid crystal display panel 100a. Compare FIGS. 1B and 10(a). In FIG. 10, in an edge region of the polarizing plate 900b running in the column direction, certain colors of light are emitted more strongly depending on the position of the edge of the polarizing plate 900b, thereby causing the rainbow effect. In contrast, in FIG. 1B, both the edges of the polarizing plate 100b that run in the column direction and the edges of the polarizing plate 100b that run in the horizontal direction intersect with different colors of pixels P, thereby allowing the primary colors to mix effectively and reducing the occurrence of the rainbow effect.

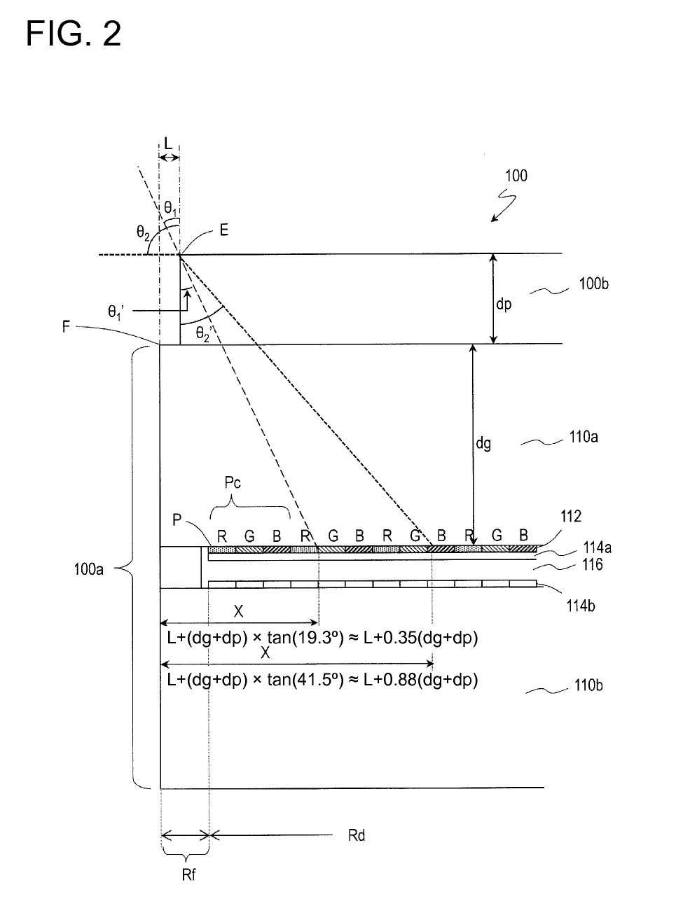

Next, the width with which the second display region R2 should be formed in order to reduce the occurrence of the rainbow effect near the edge regions will be described with reference to FIGS. 2 to 4.

FIG. 2 schematically illustrates the cross-sectional structure of an edge region of the liquid crystal display device 100. FIG. 2 is a cross-sectional view taken along a line parallel to the row direction. As illustrated in FIG. 2, the liquid crystal display device 100 includes a polarizing plate 100b arranged on the viewer's side of the liquid crystal display panel 100a. No optical members are arranged on the viewer's side of the polarizing plate 100b. In the liquid crystal display device 100, the edge E of the polarizing plate 100b has the potential to cause the rainbow effect to occur.

The liquid crystal display panel 100a includes two substrates 110a and 110b, and a liquid crystal layer 116 is formed therebetween. At least the viewer's side substrate 110a is a transparent substrate such as a glass substrate, for example. Electrodes 114a and 114b are arranged facing one another on either side of the liquid crystal layer 116 and are used to apply a voltage to the liquid crystal layer 116. The electrode 114a is the common electrode, and the electrodes 114b are pixel electrodes formed for each pixel, for example. The electrodes 114b are connected to TFTs, for example. The substrate 110a on the viewer's side of the liquid crystal layer 116 includes a color filter layer 112. The color filter layer 112 includes color filters arranged corresponding to the pixels to form the primary color pixels. In this type of liquid crystal display panel 100, the arrangement of the primary color pixels is determined by the arrangement of the color filters.

Consider the width of the second display region R2 needed to reduce the occurrence of the rainbow effect in a case such as that illustrated in FIG. 2, in which the edge E of the polarizing plate 100b is shifted away from the edge of the liquid crystal display panel 100a by a length L (in mm). In this case, the length X from the edge of the liquid crystal display panel 100a in the row direction to the boundary between the second display region R2 and the first display region R1 must be obtained. This length X is equal to the sum of the width of the second display region R2 and the width of the frame region Rf.

Let the thickness of the polarizing plate 100b be dp (in mm) and the thickness of the transparent substrate 110a be dg (in mm). Let 0 be the direction (viewing angle) from which the viewer views the panel (relative to a line normal to the substrate) and 0′ be the direction (internal angle) in which light that enters the liquid crystal display device 100 (polarizing plate 100b) travels. In this case, θ and θ′ satisfy the relationship sin θ=n·sin θ′ (Snell's law). Let the refractive index n of the polarizing plate 100b be 1.509. In this case, when θ₁=30°, θ₁′=19.3°, and when θ₂=90°, θ₂′=41.5°. For simplicity, assume that not only the polarizing plate 100b but also the transparent substrate 110a and the rest of the optical members all have a refractive index of 1.509.

Liquid crystal display devices for use in mobile devices are usually used at viewing angles of less than or equal to 30°, for example. In this case, as illustrated in FIG. 2, setting the length X to a value larger than L+0.35×(dg+dp) makes it possible to reduce the occurrence of the rainbow effect. However, because the alignment error when fixing together the liquid crystal display panel 100a and the polarizing plate 100b and the dimensional tolerances for those components is approximately 0.2 mm, it is preferable that the relationship X≧L+0.35×(dg+dp)+0.2 mm be satisfied.

Meanwhile, liquid crystal display devices for use in televisions, for example, require much wider viewing angles. Allowing the viewing angle θ₂ to be equal to 90°, as illustrated in FIG. 2, the length X is L+0.88×(dg+dp). Therefore, the length X does not need to be greater than L+0.88×(dg+dp). In other words, L+0.88×(dg+dp) is the minimum value of X at which the occurrence of the rainbow effect can be reduced even at viewing angles θ of up to 90°. However, considering as above the alignment error when fixing together the components and the dimensional tolerances for those components, it is preferable that the relationship X≦L+0.88×(dg+dp)+0.2 mm be satisfied. If X is larger than L+0.88×(dg+dp)+0.2 mm, the area of the first display region is reduced, thereby potentially decreasing the display quality during normal display. For example, when a straight line is displayed in the second display region, the viewer may see a jagged line. This effect is particularly pronounced when displaying a straight line in one of the primary colors such as R, G, or B.

Next, a specific example of a liquid crystal display device for use in a television will be described. Let dg=0.7 mm, dp=0.2 mm, and L=0.2 mm, for example. In this case, setting the length X to a value greater than or equal to the values shown below in Table 2 makes it possible to reduce the occurrence of the rainbow effect for each viewing angle. For example, setting the length X to 0.52 mm reduces occurrence of the rainbow effect up to viewing angles of 30°. To reduce the occurrence of the rainbow effect up to viewing angles of 60°, the length X should be set to 0.83 mm. Setting the length X to 1.00 mm makes it possible to reduce the occurrence of the rainbow effect at all viewing angles.

TABLE 2

| Viewing Angle θ (°) | Internal Angle θ′ (°) | Length X (mm) |
|---|---|---|
| 0 | 0.0 | 0.20 |
| 5 | 3.3 | 0.25 |
| 10 | 6.6 | 0.30 |
| 15 | 9.9 | 0.36 |
| 20 | 13.1 | 0.41 |
| 25 | 16.3 | 0.46 |
| 30 | 19.3 | 0.52 |
| 35 | 22.3 | 0.57 |
| 40 | 25.2 | 0.62 |
| 45 | 27.9 | 0.68 |
| 50 | 30.5 | 0.73 |
| 55 | 32.9 | 0.78 |
| 60 | 35.0 | 0.83 |
| 65 | 36.9 | 0.88 |
| 70 | 38.5 | 0.92 |
| 75 | 39.8 | 0.95 |
| 80 | 40.7 | 0.97 |
| 85 | 41.3 | 0.99 |
| 90 | 41.5 | 1.00 |

Note that the rainbow effect may also be visible along the edge F of the transparent substrate 110a. In this case, the length X can be calculated by setting L to 0 in the formulas above.

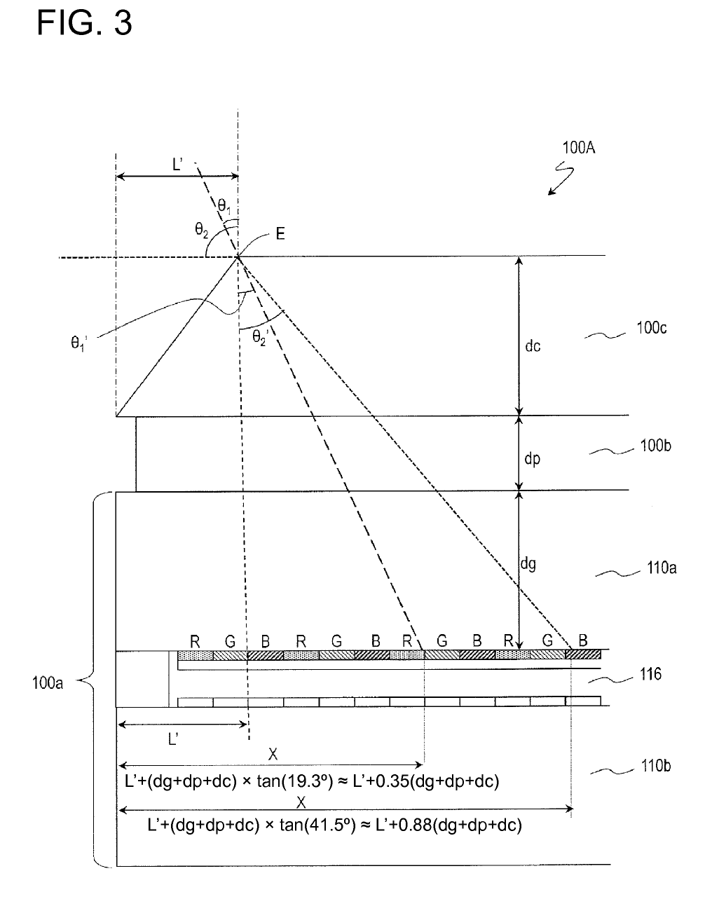

FIG. 3 is a cross-sectional view schematically illustrating a cross section taken along a line parallel to the row direction in an edge region of a liquid crystal display device 100A having an optical member 100c arranged on the viewer's side of a polarizing plate 100b. The optical member 100c is a touch panel or a transparent cover (a protective glass or resin sheet), for example. As illustrated in FIG. 3, if the optical member 100c has a viewer's side edge E, that edge E may cause the rainbow effect to occur.

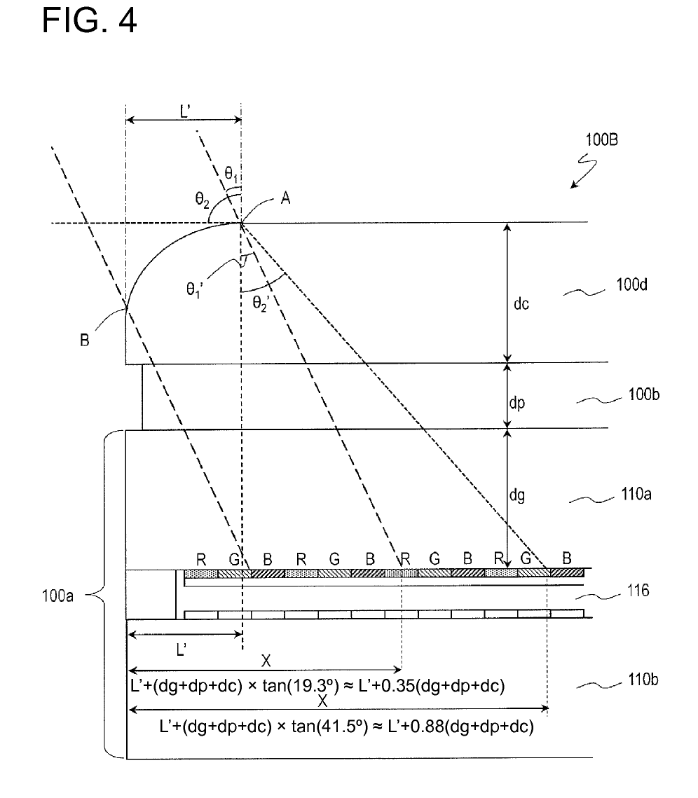

FIG. 4 is a cross-sectional view schematically illustrating a cross section taken along a line parallel to the row direction in an edge region of a liquid crystal display device 100B having an optical member 100d arranged on the viewer's side of a polarizing plate 100b. The optical member 100d is a transparent cover having a curved surface in an edge region in the row direction. This curved surface functions as a lens and makes it possible to reduce the visibility of the frame region Rf (see WO 2009/157150). When, as in the optical member 100d, the viewer's side surface includes both flat surfaces and a curved surface (that is, when the optical member includes flat portions and a lens portion), the rainbow effect may occur at the boundary lines A and B between the flat portions and the lens portion (the flat surfaces and the curved surface). Depending on the manufacturing and machining precision of the transparent cover, the surface may not be perfectly continuous along the boundary lines A and B.

The liquid crystal display devices 100A and 100B have optical members 100c and 100d, respectively, arranged on the viewer's side of the polarizing plate 100b. Therefore, as illustrated in FIGS. 3 and 4, the rainbow effect may occur at positions further interior in the display region Rd than in the liquid crystal display device 100 illustrated in FIG. 2.

Consider the width of the second display region R2 needed to reduce the occurrence of the rainbow effect in cases such as in the liquid crystal display devices 100A and 100B, in which the edge E of the optical member 100c and the boundary line A of the optical member 100d are shifted away from the edge of the liquid crystal display panel 100a by a length L′ (in mm). As before, in both of these cases, the length X from the edge of the liquid crystal display panel 100a in the row direction to the boundary between the second display region R2 and the first display region R1 must be obtained.

Again, let the thickness of the polarizing plate 100b be dp (in mm) and the thickness of the transparent substrate 110a be dg (in mm). In addition, let the thickness of the optical members 100c and 100d be dc (in mm). Let 0 be the direction (viewing angle) from which the viewer views the panel (relative to a line normal to the substrate) and 0′ be the direction (internal angle) in which light that enters the liquid crystal display devices 100A and 100B (polarizing plate 100b) travels. Here, θ and θ′ satisfy the relationship sin θ=n·sin θ′ (Snell's law). Let the refractive indices n of the polarizing plate 100b, the transparent substrate 110a, and the optical members 100c and 100d all be 1.509. In this case, when θ₁=30°, θ₁′=19.3°, and when θ₂=90°, θ₂′=41.5°.

Therefore, as illustrated in FIGS. 3 and 4, when the viewing angle θ₁ is 30°, for example, the length X is approximately equal to L′+0.35×(dg+dp+dc). As before, considering the alignment error when fixing together the components and the dimensional tolerances for those components, setting X to a value that satisfies the relationship X≧L′+0.35×(dg+dp+dc)+0.2 mm makes it possible to reduce the occurrence of the rainbow effect up to viewing angles θ₁ of 30°.

Similarly, when the viewing angle θ₂ is 90°, for example, the length X is approximately equal to L′+0.88×(dg+dp+dc). Considering again the alignment error when fixing together the components and the dimensional tolerances for those components yields X≦L′+0.88×(dg+dp+dc)+0.2 mm.

Next, a specific example of a liquid crystal display device for use in a mobile device will be described. Let dg=0.3 mm, dp=0.1 mm, dc=2.0 mm, and L′=2.0 mm, for example. In this case, setting the length X to a value greater than or equal to the values shown below in Table 3 makes it possible to reduce the occurrence of the rainbow effect for each viewing angle.

TABLE 3

| Viewing Angle θ (°) | Internal Angle θ′ (°) | Length X (mm) |
|---|---|---|
| 0 | 0.0 | 2.00 |
| 5 | 3.3 | 2.14 |
| 10 | 6.6 | 2.28 |
| 15 | 9.9 | 2.42 |
| 20 | 13.1 | 2.56 |
| 25 | 16.3 | 2.70 |
| 30 | 19.3 | 2.84 |
| 35 | 22.3 | 2.99 |
| 40 | 25.2 | 3.13 |
| 45 | 27.9 | 3.27 |
| 50 | 30.5 | 3.41 |
| 55 | 32.9 | 3.55 |
| 60 | 35.0 | 3.68 |
| 65 | 36.9 | 3.80 |
| 70 | 38.5 | 3.91 |
| 75 | 39.8 | 4.00 |
| 80 | 40.7 | 4.06 |
| 85 | 41.3 | 4.11 |
| 90 | 41.5 | 4.12 |

The calculation above was for the boundary line A. However, the same calculation may be performed for the boundary line B by assuming that the boundary line B is shifted away from the edge of the liquid crystal display panel 100a by a length L′ (in mm). Furthermore, if the boundary line B aligns with the edge of the liquid crystal display panel 100a, then L′=0.

For the configurations illustrated in FIGS. 2 to 4, let the thickness of the transparent substrate be Ts and the total thickness of the optical members arranged on the viewer's side of the transparent substrate be To (for the configurations that include both a polarizing plate and a transparent cover, To is the combined thickness of those components). In this case, the condition for reducing the occurrence of the rainbow effect for viewing angles θ of up to 30° is X≧L+0.35×(Ts+To)+0.2 mm, and the minimum value for the length X that also reduces the occurrence of the rainbow effect for viewing angles θ of up to 90° is L+0.88×(Ts+To)+0.2 mm. Furthermore, if the occurrence of the rainbow effect only has to be reduced when the panel is viewed from straight on)(θ=0°, then satisfying X≧L+0.2 mm is sufficient.

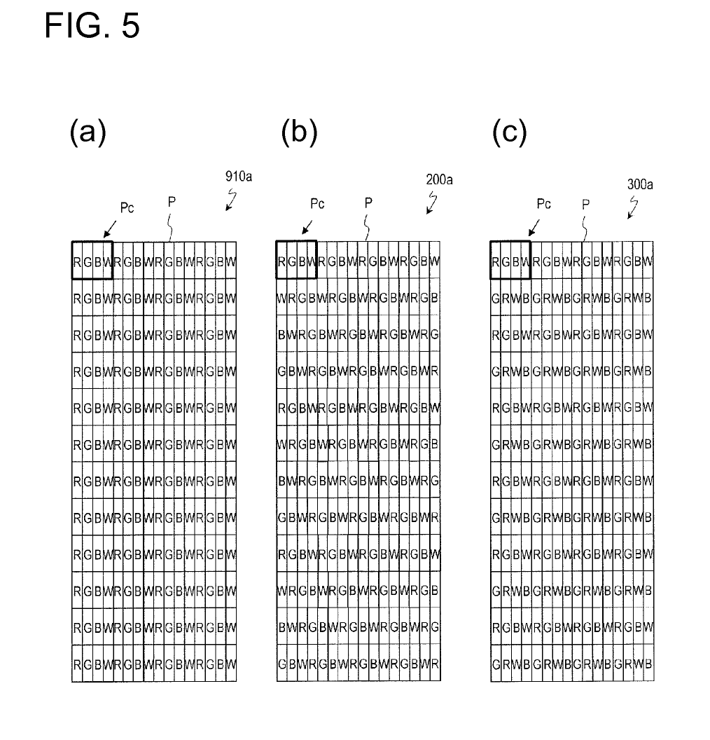

Next, primary color pixel arrangements (for the second display region) for preventing the rainbow effect in so-called multi-primary color display panels in which four or more types of primary color pixels are used will be described with reference to FIGS. 5 to 7.

The display panel 910a illustrated in FIG. 5(a) includes four types of primary color pixels P: red (R) pixels, green (G) pixels, blue (B) pixels, and white (W) pixels. Each group of four of these primary color pixels forms a single color display pixel Pc. Note that because green (G) and white (W) exhibit higher luminosity than the other two primary colors, it is preferable that pixels of these colors not be arranged adjacent to one another. It is preferable that these pixels be arranged in the following order in the row direction: red (R), green (G), blue (B), and white (W). The configuration described above is also preferable when the white (W) pixels are replaced by yellow (Y) pixels. The four types of primary color pixels P are arranged in a stripe pattern. Therefore, similar to the liquid crystal display panel 900a illustrated in FIG. 10, arranging optical members on the viewer's side of the display panel 910a may cause the rainbow effect to occur.

To prevent this, the primary color pixels P may be arranged as in the display panel 200a illustrated in FIG. 5(b). Like in the second region R2 of the liquid crystal display panel 100a illustrated in FIG. 1A, in the primary color pixel pattern illustrated in FIG. 5(b), when a color display pixel Pc(m, N) in the mth row and Nth column in the matrix is written as m·N(n₁, n₂, . . . , nₚ₋₁, nₚ), where (n₁, n₂, . . . , nₚ₋₁, nₚ) represents primary color pixels of first, second, . . . , (p−1)th, and pth colors arranged in order from left to right in the row direction, then a color display pixel Pc(m+k, N) in the (m+k)th row and Nth column in the matrix can be written as (m+k)·N(nₚ, n₁, n₂, . . . , nₚ₋₁). (Here, m, N, and n are positive integers, k is a positive integer less than or equal to 3, and p is an integer greater than or equal to 3 and less than or equal to 6).

More specifically, for p=4 and k=1, a color display pixel Pc(m, N) in the mth row and Nth column in the matrix can be written as m·N(n₁, n₂, n₃, n₄), where (n₁, n₂, n₃, n₄) represents primary color pixels of first, second, third, and fourth colors (R, G, B, and W, respectively) arranged in order from left to right in the row direction. Similarly, a color display pixel Pc(m+1, N) in the (m+1)th row and Nth column in the matrix can be written as (m+1)·N(n₄, n₁, n₂, n₃). For example, the color display pixel Pc(1, 1) in the first row and the first column can be written as (R, G, B, W), the color display pixel Pc(2, 1) in the second row and the first column can be written as (W, R, G, B), and the color display pixel Pc(3, 1) in the third row and the first column can be written as (B, W, R, G).

Furthermore, the primary color pixels P may also be arranged as in the display panel 300a illustrated in FIG. 5(c). In the primary color pixel pattern illustrated in FIG. 5(c), when a color display pixel in the mth row and Nth column is written as m·N(n₁, n₂, n₃, n₄), where (n₁, n₂, n₃, n₄) represents primary color pixels of first, second, third, and fourth colors arranged in order from left to right in the row direction, then a color display pixel in the (m+k)th row and Nth column can be written as (m+k)·N(n₂, n₁, n₄, n₃). (Here, m, N, and n are positive integers, and k is a positive integer less than or equal to 3). For example, the color display pixel Pc(1, 1) in the first row and the first column can be written as (R, G, B, W), the color display pixel Pc(2, 1) in the second row and the first column can be written as (G, R, W, B), and the color display pixel Pc(3, 1) in the third row and the first column can be written as (R, G, B, W). In other words, R and G are switched in each successive row and B and W are switched in each successive row.

Although the primary color pixel arrangement in the display panel 300a illustrated in FIG. 5(c) is less effective at preventing the rainbow effect than the primary color pixel arrangement in the display panel 200a illustrated in FIG. 5(b), the former does makes it possible to prevent straight lines from appearing jagged when displayed.

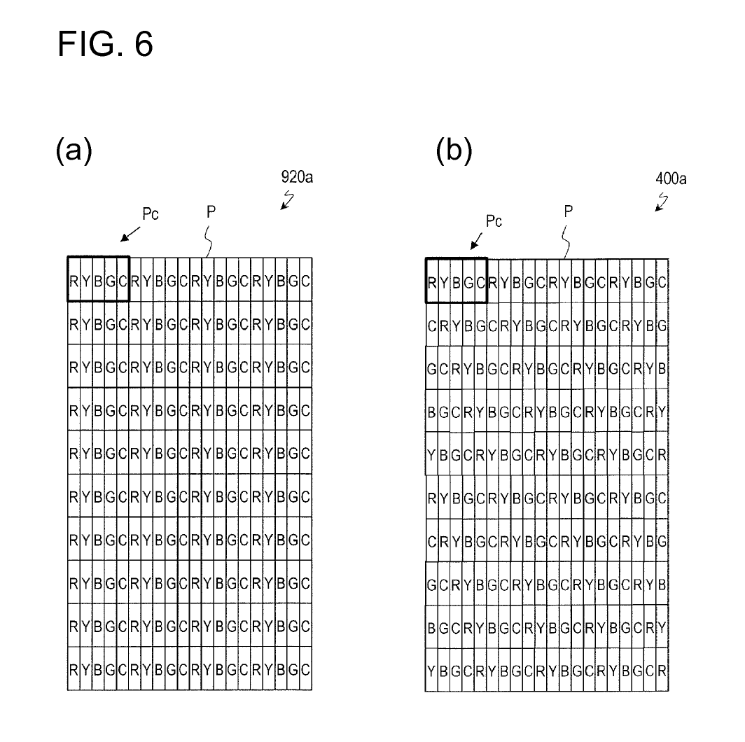

The display panel 920a illustrated in FIG. 6(a) includes five types of primary color pixels P: red (R) pixels, yellow (Y) pixels, blue (B) pixels, green (G) pixels, and cyan (C) pixels. Each group of five of these primary color pixels forms a single color display pixel Pc. Note that because green (G) and yellow (Y) exhibit higher luminosity than the other three primary colors, it is preferable that pixels of these colors not be arranged adjacent to one another. It is preferable that these pixels be arranged in the following order in the row direction: red (R), yellow (Y), blue (B), green (G), and cyan (C). The five types of primary color pixels P are arranged in a stripe pattern. Therefore, similar to the liquid crystal display panel 900a illustrated in FIG. 10, arranging optical members on the viewer's side of the display panel 920a may cause the rainbow effect to occur.

To prevent this, the primary color pixels P are arranged as in the display panel 400a illustrated in FIG. 6(b). Like in the second region R2 of the liquid crystal display panel 100a illustrated in FIG. 1A, in the primary color pixel pattern illustrated in FIG. 6(b), when a color display pixel Pc(m, N) in the mth row and Nth column in the matrix is written as m·N(n₁, n₂, . . . , nₚ₋₁, nₚ), where (n₁, n₂, . . . , nₚ₋₁, nₚ) represents primary color pixels of first, second, . . . , (p−1)th, and pth colors arranged in order from left to right in the row direction, then a color display pixel Pc(m+k, N) in the (m+k)th row and Nth column in the matrix can be written as (m+k)·N(nₚ, n₁, n₂, . . . , nₚ₋₁). (Here, m, N, and n are positive integers, k is a positive integer less than or equal to 3, and p is an integer greater than or equal to 3 and less than or equal to 6).

More specifically, for p=5 and k=1, a color display pixel Pc(m, N) in the mth row and Nth column in the matrix can be written as m·N(n₁, n₂, n₃, n₄, n₅), where (n₁, n₂, n₃, n₄, n₅) represents primary color pixels of first, second, third, fourth, and fifth colors (R, Y, B, G, and C, respectively) arranged in order from left to right in the row direction. Similarly, a color display pixel Pc(m+1, N) in the (m+1)th row and Nth column in the matrix can be written as (m+1)·N(n₅, n₁, n₂, n₃, n₄). For example, the color display pixel Pc(1, 1) in the first row and the first column can be written as (R, Y, B, G, C), the color display pixel Pc(2, 1) in the second row and the first column can be written as (C, R, Y, B, G), and the color display pixel Pc(3, 1) in the third row and the first column can be written as (G, C, R, Y, B).

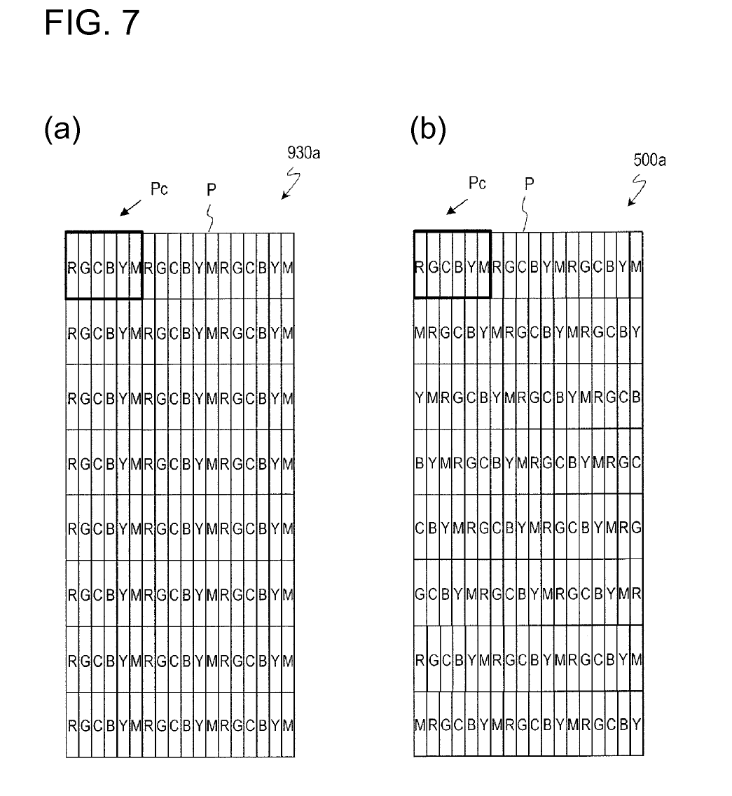

The display panel 930a illustrated in FIG. 7 includes six types of primary color pixels P: red (R) pixels, green (G) pixels, cyan (C) pixels, blue (B) pixels, yellow (Y) and magenta (M) pixels. Each group of six of these primary color pixels forms a single color display pixel Pc. Note that because green (G) and yellow (Y) exhibit higher luminosity than the other three primary colors, it is preferable that pixels of these colors be arranged as far away as possible from one another (that is, at least two pixels away from one another). Moreover, it is preferable that the blue (B) and magenta (M) pixels that have a relatively low luminosity be arranged on either side of the yellow (Y) pixels that have the highest luminosity. Therefore, it is preferable that these six types of primary color pixels P be arranged in the following order in the row direction: red (R), green (G), cyan (C), blue (B), yellow (Y), and magenta (M). The six types of primary color pixels P are arranged in a stripe pattern. Therefore, similar to the liquid crystal display panel 900a illustrated in FIG. 10, arranging optical members on the viewer's side of the display panel 930a may cause the rainbow effect to occur.

To prevent this, the primary color pixels P are arranged as in the display panel 500a illustrated in FIG. 7(b). Like in the second region R2 of the liquid crystal display panel 100a illustrated in FIG. 1A, in the primary color pixel pattern illustrated in FIG. 7(b), when a color display pixel Pc(m, N) in the mth row and Nth column in the matrix is written as m·N(n₁, n₂, . . . , nₚ₋₁, nₚ), where (n₁, n₂, . . . , nₚ₋₁, nₚ) represents primary color pixels of first, second, . . . , (p−1)th, and pth colors arranged in order from left to right in the row direction, then a color display pixel Pc(m+k, N) in the (m+k)th row and Nth column in the matrix can be written as (m+k)·N(nₚ, n₁, n₂, . . . , nₚ₋₁). (Here, m, N, and n are positive integers, k is a positive integer less than or equal to 3, and p is an integer greater than or equal to 3 and less than or equal to 6).

More specifically, for p=7 and k=1, a color display pixel Pc(m, N) in the mth row and Nth column in the matrix can be written as m·N(n₁, n₂, n₃, n₄, n₅, n₆), where (n₁, n₂, n₃, n₄, n₅, n₆) represents primary color pixels of first, second, third, fourth, fifth, and sixth colors (R, G, C, B, Y, and M, respectively) arranged in order from left to right in the row direction. Similarly, a color display pixel Pc(m+1, N) in the (m+1)th row and Nth column in the matrix can be written as (m+1)·N(n₆, n₁, n₂, n₃, n₄, n₅). For example, the color display pixel Pc(1, 1) in the first row and the first column can be written as (R, G, C, B, Y, M), the color display pixel Pc(2, 1) in the second row and the first column can be written as (M, R, G, C, B, Y), and the color display pixel Pc(3, 1) in the third row and the first column can be written as (Y, M, R, G, C, B).

Furthermore, in display panel configurations such as that illustrated in FIG. 7 in which each color display pixel Pc includes six primary color pixels P, the magenta (M) pixels may be replaced by red (R) pixels. In other words, each color display pixel Pc may include two red (R) pixels. In this case, it is preferable that the six types of primary color pixels P be arranged in the following order in the row direction: R, C, G, R, B, Y. The primary color pixel arrangement for preventing the rainbow effect may be the same as in FIG. 7(b).

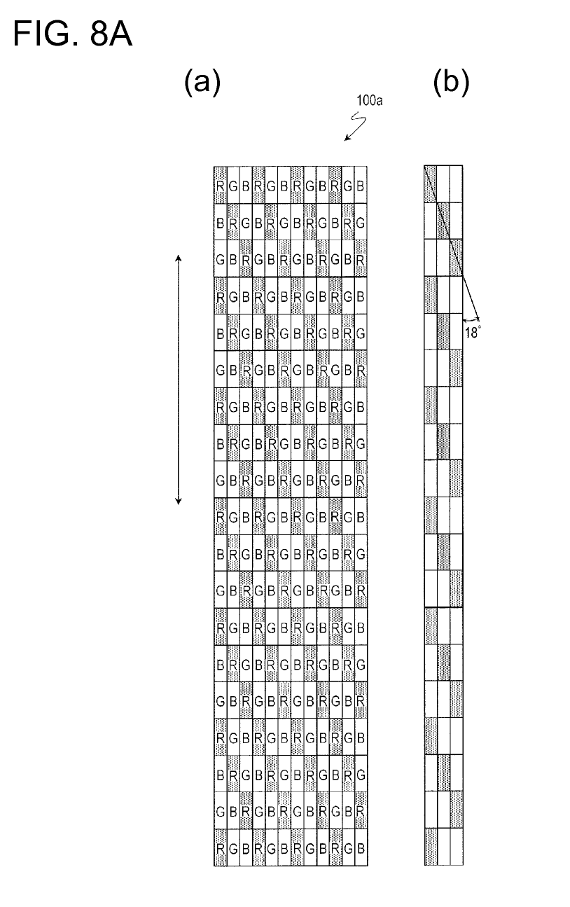

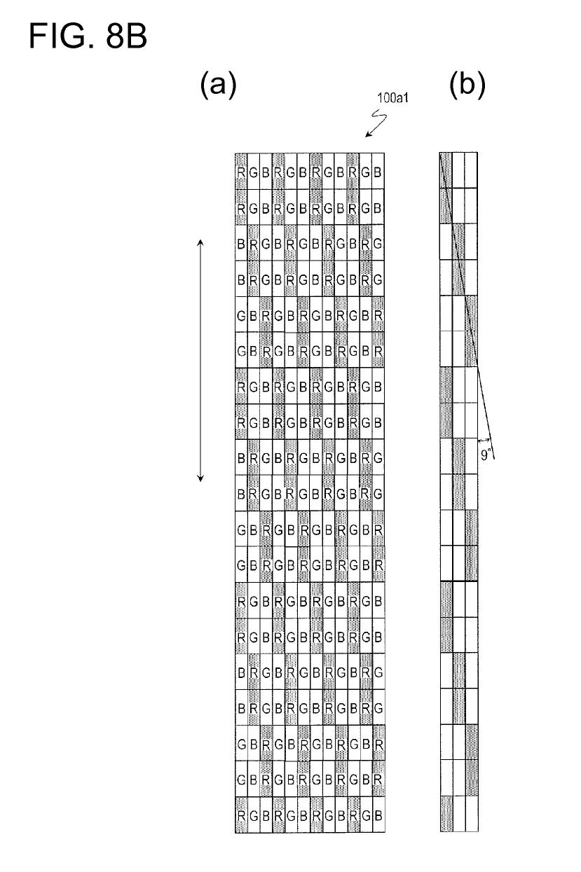

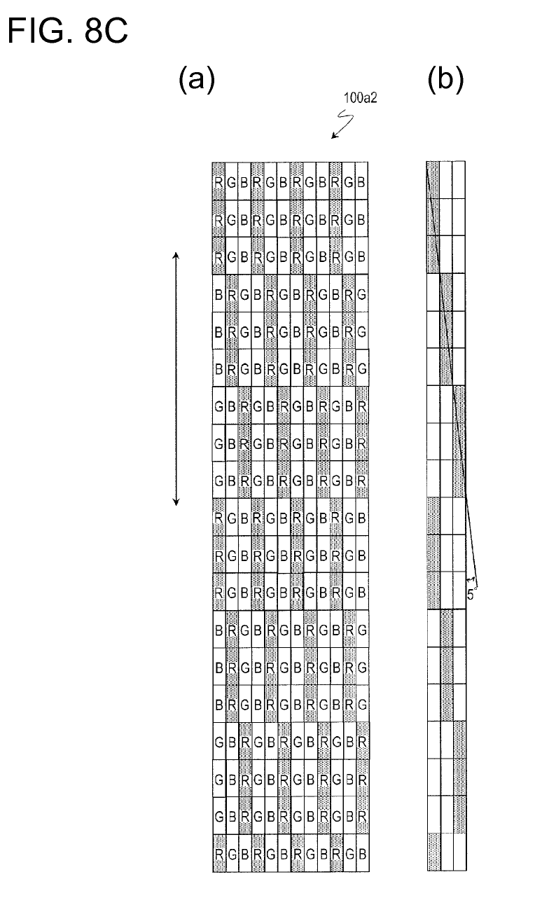

In the examples above, a different color of primary color pixel is used every one primary color pixel in the column direction (that is, k=1). However, the present invention is not limited to these types of patterns. Next, patterns with different k values will be described with reference to FIGS. 8A, 8B, and 8C.

FIG. 8A(a) illustrates a primary color pixel P arrangement (a second pattern) for use in the second display region R2 of the liquid crystal display panel 100a. FIG. 8A(b) schematically illustrates a case in which this pattern is used to display straight red (R) lines.

As illustrated in FIG. 8A(a), in the second pattern of the liquid crystal display panel 100a, when a color display pixel Pc(m, N) in the mth row and Nth column in the matrix is written as m·N(n₁, n₂, n₃), where (n₁, n₂, n₃) represents R, G, and B primary color pixels, respectively, arranged in order from left to right in the row direction, then a color display pixel Pc(m+1, N) in the (m+1)th row and Nth column in the matrix can be written as (m+1)·N(B, R, G). (Here, p=3 and k=1). In other words, a different color of primary color pixel is used every one primary color pixel in the column direction.

Letting the pitch of the primary color pixel pattern in the row direction be Px and the pitch of the primary color pixel pattern in the column direction be Py, then Px=Py/3 for most three primary color configurations. This is because each color display pixel Pc is approximately square-shaped.

When Px=Py/3 and a k=1 pattern such as that illustrated in FIG. 8A(a) is used, a plurality of lines inclined at approximately 18° must be used to display a straight red line that is parallel to the column direction, as illustrated in FIG. 8A(b).

Meanwhile, when k=2, as in the liquid crystal display panel 100a1 illustrated in FIG. 8B(a), a plurality of lines inclined at approximately 9° are used to display a straight red line that is parallel to the column direction, as illustrated in FIG. 8B(b).

Furthermore, when k=3, as in the liquid crystal display panel 100a2 illustrated in FIG. 8C(a), a plurality of lines inclined at approximately 5° are used to display a straight red line that is parallel to the column direction, as illustrated in FIG. 8C(b).

Comparing FIGS. 8A(b) to 8C(b) makes it clear that the pattern illustrated in FIG. 8C is preferable for displaying straight lines.

Experiments performed by the inventor revealed that occurrence of the rainbow effect is most effectively reduced when the angle of inclination illustrated in FIGS. 8A(b) to 8C(b) (that is, tan⁻¹(Px/(k·Py))) is 22.5°. Therefore, the pattern illustrated in FIG. 8A is the most effective of the patterns illustrated in FIGS. 8A, 8B, and 8C at reducing the occurrence of the rainbow effect.

Note that the aspect ratio (Py:Px) of the pixel pitches is not limited to 3:1. As long as the primary color pixels are arranged (that is, a k value is chosen) such that tan⁻¹(Px/(k·Py)) is less than or equal to approximately 25°, the occurrence of the rainbow effect can be reduced.

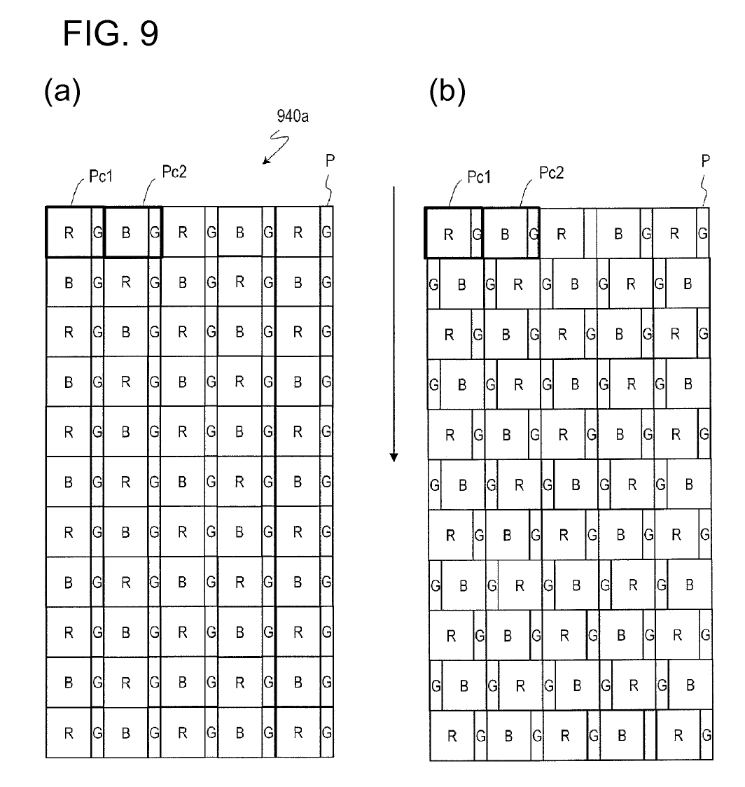

Next, examples of patterns other than stripe patterns will be described with reference to FIG. 9.

In the display panel 940a illustrated in FIG. 9(a), the primary color pixels are arranged in a pattern having a PenTile structure. A color display pixel Pc1 includes an R pixel and a G pixel, and a color display pixel Pc2 includes a G pixel and a G pixel. The G pixels are aligned in the column direction, and therefore like in some of the examples described above, this pattern may cause the rainbow effect to occur. In this example, the G pixels are aligned in the column direction, but the same is true of patterns in which the B pixels are aligned in the column direction.

To prevent this, as illustrated in FIG. 9(b), the primary color pixel columns that contain the G pixels are arranged such that the G pixel alternates with a primary color pixel of a color other than G (an R pixel or a B pixel) every successive row.

Primary color pixel patterns that have a PenTile structure are suitable for use not only in liquid crystal display panels but also in organic electroluminescent display panels. The examples of stripe patterns described above for liquid crystal display panels are also of course suitable for application to organic electroluminescent display panels. In most organic electroluminescent display devices, a circularly polarizing plate and a transparent cover are provided in order from the transparent substrate side on the viewer's side of the organic electroluminescent display panel. One of these components may also be removed.

Furthermore, display signals may be sent according to the arrangement of the primary color pixels in order to drive the display device according to the embodiment of the present invention. For a liquid crystal display panel that uses a stripe pattern, for example, display signals that correspond to one primary color may be sent to each pixel column. In the liquid crystal display device 100 according to the embodiment of the present invention, the first display region may be driven the same as in conventional technologies, and the second display region may be driven by sending display signals corresponding to the three primary colors according to the arrangement of primary color pixels in each pixel column and at prescribed times. As described above, the driving scheme used in the display device according to the embodiment of the present invention may easily be implemented on the basis of conventional driving schemes by a person skilled in the art, and therefore a detailed description of the driving scheme is omitted here.

The present specification discloses a display device according to the following Items.

<Item 1>

A display device, including:

a color display panel including a transparent substrate arranged on a viewer's side; and

an optical member arranged on the viewer's side of the color display panel,

wherein the color display panel includes a display region in which a plurality of color display pixels are arranged into rows and columns to form a matrix pattern,

wherein each of the plurality of color display pixels includes a plurality of primary color pixels of different colors arranged in a row direction,

wherein the display region includes a first display region and a second display region having mutually different arrangement patterns of the colors of the primary color pixels, such that the first display region has a first pattern in which the primary color pixels of a same color are arranged in a column direction, and such that the second display region has a second pattern in which the primary color pixels of different colors are repeated in the column direction at a prescribed interval, and

wherein the second display region includes at least one column of the color display pixels positioned on one end of the display region in the row direction.

The display device according to item 1 makes it possible to reduce the occurrence of the rainbow effect in an edge region of the device.

<Item 2>

The display device according to item 1, wherein in the second pattern, the primary color pixels of different colors are arranged every k primary color pixel interval in the column direction, where k is a positive integer less than or equal to 3.

The display device according to item 2 makes it possible to effectively reduce the occurrence of the rainbow effect in an edge region of the device.

<Item 3>

The display device according to item 2, wherein tan⁻¹(Px/(k·Py)) is less than or equal to 25°, where Px is an arrangement pitch of the primary color pixels in the row direction and Py is an arrangement pitch of the primary color pixels in the column direction.

The display device according to item 3 makes it possible to effectively reduce the occurrence of the rainbow effect in an edge region of the device.

<Item 4>

The display device according to item 2, wherein when the color display pixel in an m^{th} row and N^{th} column in the matrix pattern is expressed as m·N(n₁, n₂, . . . , nₚ₋₁, nₚ) where (n₁, n₂, . . . , nₚ₋₁, nₚ) represents the primary color pixels of first, second, . . . , (p−1)^{th}, and p^{th} colors arranged in order from left to right in the row direction, then the color display pixel in an (m+k)^{th} row and N^{th} column in the matrix pattern is expressed as (m+k)·N(nₚ, n₁, n₂, . . . , nₚ₋₁), where m, N, and n are positive integers and p is an integer from 3 to 6.

<Item 5>

The display device according to item 2, wherein when the color display pixel in an m^{th} row and N^{th} column in the matrix pattern is expressed as m·N(n₁, n₂, n₃, n₄), where (n₁, n₂, n₃, n₄) represents the primary color pixels of first, second, third, and fourth colors arranged in order from left to right in the row direction, then the color display pixel in an (m+k)^{th} row and N^{th} column in the matrix pattern is expressed as (m+k)·N(n₂, n₁, n₄, n₃), where m, N, and n are positive integers.

<Item 6>

The display device according to item 5, wherein the first, second, and third colors are red, green, and blue, respectively, and the fourth color is white or yellow.

<Item 7>

The display device according to any one of items 1 to 6,

wherein the optical member includes an edge line or a boundary line parallel to an edge of the color display panel in the row direction,

wherein when L is a length from the edge of the color display panel in the row direction to the edge line or the boundary line when the transparent substrate is viewed from a direction normal thereto, Ts is a thickness of the transparent substrate, and To is a thickness of the optical member along the edge line or the boundary line, then X satisfies X≧L+0.2 mm, where X is a length from the edge of the color display panel in the row direction to a boundary between the first display region and the second display region on one end of the display region.

The display device according to item 7 makes it possible to reduce effectively the occurrence of the rainbow effect in an edge region of the device when the viewing angle is 0°. If the length X satisfies X≧L+0.35×(Ts+To)+0.2 mm, occurrence of the rainbow effect can be reduced for viewing angles of up to 30°.

<Item 8>

The display device according to item 7, wherein the length X from the edge of the color display panel in the row direction to the boundary between the first display region and the second display region on one end of the display region satisfies X≦L+0.88×(Ts+To)+0.2 mm.

The display device according to item 8 makes it possible to effectively reduce the occurrence of the rainbow effect in an edge region of the device for substantially all viewing angles.

<Item 9>

The display device according to any one of items 1 to 8,

wherein the optical member includes a flat portion where a surface of the optical member on the viewer's side is flat, and a lens portion adjacent to the flat portion in the row direction, and

wherein the boundary line is a boundary line between the flat portion and the lens portion.

The display device according to item 9 makes it possible to reduce the visibility of the frame region and to reduce effectively the occurrence of the rainbow effect in an edge region of the device.

<Item 10>

The display device according to any one of items 1 to 9, wherein the second display region further includes one column of the color display pixels positioned on another end of the display region in the row direction.

The display device according to item 10 makes it possible to reduce the occurrence of the rainbow effect on both edge regions of the device.

<Item 11>

The display device according to any one of items 1 to 10, wherein the primary color pixels respectively include color filters.

<Item 12>

The display device according to item 11,

wherein the color display panel is a liquid crystal display panel, and

wherein the optical member includes a polarizing plate and a transparent cover arranged in that order from the transparent substrate side of the color display panel.

<Item 13>

A display device, including:

a color display panel including a transparent substrate arranged on a viewer's side; and

an optical member arranged on the viewer's side of the color display panel,

wherein the color display panel includes a display region in which a plurality of color display pixels are arranged into rows and columns to form a matrix pattern,

wherein each of the plurality of color display pixels includes a plurality of primary color pixels of different colors arranged in a row direction,

wherein the display region includes a first display region and a second display region having mutually different arrangement patterns of the colors of the primary color pixels, such that the first display region has a first pattern having a PenTile structure that includes primary color pixel columns in which the primary color pixels having a first color are arranged in the column direction, and such that the second display region has a second pattern in which the columns of the primary color pixels that include the primary color pixels of the first color are arranged such that the primary color pixels of the first color alternate with the primary color pixels of a second color that is different from the first color, and

wherein the second display region includes at least one column of the color display pixels positioned on one end of the display region in the row direction.

In the display device according to item 13, the arrangement of the primary color pixels has a PenTile structure, thereby making it possible to reduce the occurrence of the rainbow effect in an edge region of the device.

<Item 14>

The display device according to item 13, wherein the first color is green or blue, and the second color is red.

<Item 15>

The display device according to any one of items 1 to 14,

wherein the color display panel is an organic electroluminescent display panel, and

wherein the optical member includes a circularly polarizing plate and a transparent cover arranged in that order starting from a transparent substrate side of the color display panel.

### INDUSTRIAL APPLICABILITY

The present invention is widely applicable to color display devices such as liquid crystal display devices and organic electroluminescent display devices.

### DESCRIPTION OF REFERENCE CHARACTERS

100a liquid crystal display panel
100 liquid crystal display device
R1 first display region
R2 second display region
Pc color display pixel
P primary color pixel
Rd display region
Rf frame region

1: A display device, comprising:
a color display panel including a transparent substrate arranged on a viewer's side; and
an optical member arranged on the viewer's side of the color display panel,
wherein the color display panel includes a display region in which a plurality of color display pixels are arranged into rows and columns to form a matrix pattern,
wherein each of the plurality of color display pixels includes a plurality of primary color pixels of different colors arranged in a row direction,
wherein the display region includes a first display region and a second display region having mutually different arrangement patterns of the colors of the primary color pixels, such that the first display region has a first pattern in which the primary color pixels of a same color are arranged in a column direction, and such that the second display region has a second pattern in which the primary color pixels of all of the different colors are repeated in the column direction at a prescribed interval in each column, and
wherein the second display region includes at least one column of the color display pixels positioned on one end of the display region in the row direction.

2: The display device according to claim 1, wherein in the second pattern, the primary color pixels of different colors are repeated every k primary color pixel interval in the column direction with k rows of primary color pixels having the same color, where k is a positive integer less than or equal to 3.

3: The display device according to claim 2, wherein, in the second pattern, tan⁻¹(Px/(k·Py)) is less than or equal to 25°, where Px is an arrangement pitch of the primary color pixels in the row direction and Py is an arrangement pitch of the primary color pixels in the column direction.

4: The display device according to claim 2, wherein, in the second pattern, the primary color pixels are arranged such that, at the color display pixel in an m^{th} row and N^{th} column in the matrix pattern, the primary color pixels of first, second, . . . , (p−1)^{th}, and p^{th} colors which are respectively represented as n₁, n₂, . . . , nₚ₋₁, nₚ, are arranged in order from left to right in the row direction, and at the color display pixel in an (m+k)^{th} row and N^{th} column in the matrix pattern, the primary color pixels are arranged in the order of nₚ, n₁, n₂ . . . , nₚ₋₁ from left to right in the row direction, where m, N, and n are positive integers and p is an integer from 3 to 6.

5: The display device according to claim 2, wherein, in the second pattern, the primary color pixels are arranged such that, at the color display pixel in an m^{th} row and N^{th} column in the matrix pattern, the primary color pixels of first, second, third, and fourth colors, which are represented as n₁, n₂, n₃, n₄, are arranged in order from left to right in the row direction, and at the color display pixel in an (m+k)^{th} row and N^{th} column in the matrix pattern, the primary color pixels are arranged in the order of n₂ n₁, n₄ n₃ from left to right in the row direction, where m, N, and n are positive integers.

6: The display device according to claim 5, wherein the first, second, and third colors are red, green, and blue, respectively, and the fourth color is white or yellow.

7: The display device according to claim 1,
wherein the optical member includes an edge line or a boundary line parallel to an edge of the color display panel in the row direction,
wherein when L is a length from the edge of the color display panel in the row direction to the edge line or the boundary line when the transparent substrate is viewed from a direction normal thereto, X satisfies X≧L+0.2 mm, where X is a length from the edge of the color display panel in the row direction to a boundary between the first display region and the second display region on one end of the display region.

8: The display device according to claim 7, wherein the length X from the edge of the color display panel in the row direction to the boundary between the first display region and the second display region on one end of the display region satisfies X≦L+0.88×(Ts+To)+0.2 mm, where Ts is a thickness of the transparent substrate, and To is a thickness of the optical member along the edge line or the boundary line.

9: The display device according to claim 8,
wherein the optical member includes a flat portion where a surface of the optical member on the viewer's side is flat, and a lens portion adjacent to the flat portion in the row direction, and
wherein the boundary line is a boundary line between the flat portion and the lens portion.

10: The display device according to claim 1, wherein the second display region further includes at least one column of the color display pixels positioned on another end of the display region in the row direction.

11: The display device according to claim 1, wherein the primary color pixels respectively include color filters.

12: The display device according to claim 11,
wherein the color display panel is a liquid crystal display panel, and
wherein the optical member includes a polarizing plate and a transparent cover arranged in that order from a transparent substrate side of the color display panel.

13: A display device, comprising:
a color display panel including a transparent substrate arranged on a viewer's side; and
an optical member arranged on the viewer's side of the color display panel,
wherein the color display panel includes a display region in which a plurality of color display pixels are arranged into rows and columns to form a matrix pattern,
wherein each of the plurality of color display pixels includes a plurality of primary color pixels of different colors arranged in a row direction,
wherein the display region includes a first display region and a second display region having mutually different arrangement patterns of the colors of the primary color pixels, such that the first display region has a first pattern having a PenTile structure that includes primary color pixel columns in which the primary color pixels having a first color are arranged in the column direction in each column, and such that the second display region has a second pattern in which said primary color pixels of said first color alternate in the column direction with the primary color pixels of a color that is different from the first color, and
wherein the second display region includes at least one column of the color display pixels positioned on one end of the display region in the row direction.

14: The display device according to claim 13, wherein the first color is green, and the color that is different from the first color is blue or red.

15: The display device according to claim 1,
wherein the color display panel is an organic electroluminescent display panel, and
wherein the optical member includes a circularly polarizing plate and a transparent cover arranged in that order starting from a transparent substrate side of the color display panel.

16: The display device according to claim 13,
wherein the color display panel is an organic electroluminescent display panel, and
wherein the optical member includes a circularly polarizing plate and a transparent cover arranged in that order starting from a transparent substrate side of the color display panel.
